(19) United States
(12) Patent Application Publication
(10) Pub. No.: US 2026/0098879 A1
(43) Pub. Date: Apr. 9, 2026

(54) CURRENT SENSE AMPLIFIER

(71) Applicant: WILL SEMICONDUCTOR (SHANGHAI) CO. LTD., SHANGHAI (CN)

(72) Inventor: HIROYUKI KIMURA, MIYAGI (JP)

(21) Appl. No.: 19/077,577

(22) Filed: Mar. 12, 2025

(30) Foreign Application Priority Data
Oct. 4, 2024 (JP) 2024-175364

(51) Int. Cl. G01R 19/00; H03F 3/45

(52) U.S. Cl. CPC G01R 19/0023; H03F 3/45475; H03F 2200/129; H03F 2200/462; H03F 2203/45022; H03F 2203/45151

(57) ABSTRACT

A preamplifier obtains a preamplifier positive output and a preamplifier negative output; and a post-amplifier has a positive input end to which the preamplifier positive output is input and a negative input end to which the preamplifier negative output is input, and obtains a post-amplifier output. The post-amplifier includes: a positive side input resistor disposed in an input path to the positive input end; a negative side input resistor disposed in an input path to the negative input end; a feedback resistor disposed in a feedback path from a post-amplifier output end to the negative input end; and a resistor network in which an offset voltage obtained by performing resistance division to the voltage of the reference power supply is supplied to the positive input end, and a combined resistance value corresponds to the resistance value of the feedback resistor.

### BACKGROUND OF THE INVENTION

### 1. Field of the Invention

The disclosure relates to a current sense amplifier for detecting the current flowing through a current detection resistor.

### 2. Description of the Related Art

In a drive circuit for driving a load such as a motor, a drive transistor controlling a drive current is used. In order to control the drive current of the motor, it is necessary to detect the current flowing through the drive transistor, and a current sense amplifier is used to detect the drive current of the motor.

Here, a power metal-oxide-semiconductor field-effect transistor (MOSFET) is often used as the drive transistor, but this power MOSFET is relatively large for allowing a large current to flow, and is often externally attached to a semiconductor substrate constituting the drive circuit for use.

In such a case, the drive current of the motor can be detected by connecting a current detection resistor in series to the power MOSFET outside the semiconductor substrate, and detecting a voltage drop in the current detection resistor by a current sense amplifier in the semiconductor substrate.

### PRIOR ART DOCUMENTS

### Patent Documents

[Patent document 1] Japanese published unexamined application No. 7-113826

### SUMMARY OF THE INVENTION

### Problems to be Solved

In such a current sense amplifier, a single-end output at a desired offset voltage is desired, and noise and the like are desired to be as small as possible at this time.

### Means to Solve Problems

A current sense amplifier according to an aspect of the disclosure includes: a preamplifier that has a preamplifier positive input end to which an upper voltage of a current detection resistor is input and a preamplifier negative input end to which a lower voltage of the current detection resistor is input, and obtains a preamplifier positive output at a positive output end and obtains a preamplifier negative output at a negative output end in accordance with a difference between the upper voltage and the lower voltage; and a post-amplifier that has a post-amplifier negative input end to which the preamplifier negative output is input and a post-amplifier positive input end to which the preamplifier positive output is input, and obtains a post-amplifier output corresponding to a difference between the preamplifier positive output and the preamplifier negative output; where the post-amplifier includes: a second operational amplifier in which the preamplifier negative output is input to a second operational amplifier negative input end, the preamplifier positive output is input to a second operational amplifier positive input end, and a second operational amplifier output is obtained based on a difference between them; a second operational amplifier positive side input resistor disposed in an input path to the second operational amplifier positive input end; a second operational amplifier negative side input resistor disposed in an input path to the second operational amplifier negative input end; a second operational amplifier feedback resistor disposed in a feedback path from a second operational amplifier output end to the second operational amplifier negative input end; and a resistor network which connects the second operational amplifier positive input end to a reference power supply and a ground, and in which a combined resistance value from the second operational amplifier positive input end to the reference power supply and the ground corresponds to the resistance value of the second operational amplifier feedback resistor.

Preferably, the resistor network includes a set resistor of which one end is connected to the second operational amplifier positive input end, and a division resistor that obtains a voltage divided at an intermediate point of a plurality of series-connected resistors disposed between the reference power supply and the ground, and the other end of the set resistor is connected to the intermediate point.

Preferably, the current sense amplifier includes: an insertion resistor inserted between the other end of the set resistor and the intermediate point; a parallel resistor of which one end is connected to the ground; and a switch that selectively connects either the connection point between the set resistor and the insertion resistor or the other end of the parallel resistor to the intermediate point; where by the switch, the voltage supplied to the other end of the set resistor is able to be changed while the resistance value from the other end of the set resistor to the reference power supply and the ground is maintained.

Preferably, the resistance values of the second operational amplifier feedback resistor and the set resistor are able to be changed, and when the resistance value of the second operational amplifier feedback resistor is changed, a combined resistance value of the resistor network is maintained to be the same as the resistance value of the second operational amplifier feedback resistor by changing the resistance value of the set resistor.

In addition, a current sense amplifier related to the disclosure is a current sense amplifier, in which a pair of input signals corresponding to a voltage drop of a current detection resistor is input and an amplifier output is obtained, the current sense amplifier including: a positive input end to which a positive side signal of the pair of input signals is input; a negative input end to which a negative side signal of the pair of input signals is input; an output end that outputs an amplifier output corresponding to a difference between the positive side signal and the negative side signal; a positive side input resistor disposed in an input path to the positive input end; a negative side input resistor disposed in an input path to the negative input end; a feedback resistor disposed in a feedback path from the output end to the second operational amplifier negative input end; and a resistor network which connects the positive input end to a reference power supply and a ground, and in which a combined resistance value from the positive input end to the reference power supply and the ground corresponds to the resistance value of a second operational amplifier feedback resistor.

### Effects

According to the post-amplifier related to the disclosure, by the resistor network, the offset voltage of the output can be set, and there is no need to use a component that causes noise, such as a buffer amplifier.

In addition, because it is able to change the resistance value of the resistor network by the switch, the offset voltage of the post-amplifier can be adjusted without changing the gain.

### BRIEF DESCRIPTION OF THE DRAWINGS

FIG. 1 is a circuit diagram showing a configuration of a current sense amplifier according to an embodiment.

FIG. 2 is a diagram showing a common mode operation of an operational amplifier opa1 in a preamplifier 10.

FIG. 3 is a diagram showing a detailed configuration of the operational amplifier opa1.

FIG. 4 is a diagram showing a configuration in a case where p-channel transistors Mp3 and Mp4 are used instead of n-channel transistors Mn1 and Mn2 in the configuration of FIG. 3.

### PREFERRED EMBODIMENT OF THE PRESENT INVENTION

Hereinafter, embodiments of the disclosure are described with reference to the drawings. Note that, the following embodiments do not limit the scope of the disclosure, and configurations obtained by selectively combining multiple examples are also included in the disclosure.

### “Overall Configuration”

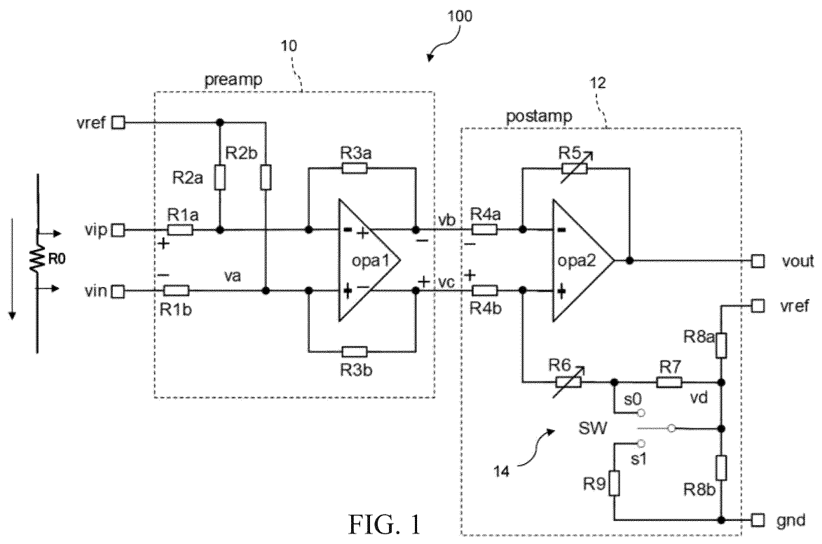

FIG. 1 is a circuit diagram showing a configuration of a current sense amplifier according to an embodiment. A current sense amplifier 100 detects a current flowing through a current detection resistor R0 connected in series to a load. Here, the load is, for example, a motor, and a current flowing through the load, for example, a drive current of the motor, is controlled by a drive transistor connected in series to the load and the current detection resistor R0. For the control of the drive current, for example, PWM control is used. In addition, as the transistor, for example, a MOSFET (metal-oxide-semiconductor field-effect transistor) is used.

The current sense amplifier 100 includes two blocks, namely a preamplifier 10 and a post-amplifier 12. In this example, the current sense amplifier 100 is formed in a semiconductor substrate as a semiconductor integrated circuit, and the current detection resistor R0 is externally attached to the semiconductor substrate and is connected in series to the drive transistor and the load outside the semiconductor substrate.

In the preamplifier 10, voltages across the current detection resistor R0 (an upper voltage vip and a lower voltage vin) are input to a preamplifier positive input end and a preamplifier negative input end, respectively. The preamplifier 10 outputs a positive-side output voltage and a negative-side output voltage corresponding to a difference between the upper voltage vip and the lower voltage vin as a preamplifier negative output vb and a preamplifier positive output vc.

The upper voltage vip is input to a negative input end (−) of an operational amplifier opa1 via a negative input resistor R1a. The lower voltage vin is input to a positive input end (+) of the operational amplifier opa1 via a positive input resistor R1b. The operational amplifier opa1 is referred to as a first operational amplifier.

A positive output end and the negative input end of the operational amplifier opa1 are connected by a negative feedback resistor R3a, and a negative output end and the positive input end of the operational amplifier opa1 are connected by a negative feedback resistor R3b. A pair of outputs of the operational amplifier opa1 directly become the output of the preamplifier 10. The voltage of the preamplifier negative output vb is denoted by vb, and the voltage of the preamplifier positive output vc is denoted by vc. The preamplifier negative output vb is input to a post-amplifier negative input end of the post-amplifier 12, and the preamplifier positive output vc is input to a post-amplifier positive input end of the post-amplifier 12.

Further, in the embodiment, the negative input end of the operational amplifier opa1 is connected to a reference power supply vref that outputs a reference voltage vref via a first input adjustment resistor R2a, and the positive input end is connected to the reference power supply vref via a second input adjustment resistor R2b. Note that, a power supply that supplies the reference voltage vref to the operational amplifier opa1 is referred to as a constant voltage source.

In this way, the preamplifier 10 is a fully differential amplifier, and the gain is determined by the resistance values of the resistors R1a, R1b, R3a, and R3b described above. In addition, the DC voltages of the negative input end and the positive input end of the operational amplifier opa1 are set according to the resistance values of the input adjustment resistors R2a and R2b.

The post-amplifier 12 has an operational amplifier opa2 therein. A pair of the preamplifier negative output vb and the preamplifier positive output vc of the preamplifier 10 are input to a pair of inputs of the operational amplifier opa2, respectively. That is, the preamplifier outputs vb and vc are input to a negative input end (−) and a positive input end (+) of the operational amplifier opa2 through a negative-side input resistor R4a and a positive-side input resistor R4b, respectively. The operational amplifier opa2 is referred to as a second operational amplifier.

The operational amplifier opa2 is a single-ended operational amplifier having one output, and a post-amplifier output vout which is a single voltage output is obtained. Further, the post-amplifier output vout becomes an output signal of the current sense amplifier 100. By the operational amplifier opa2, a single post-amplifier output vout suitable for the input to an ADC (analog-to-digital converter) can be obtained.

A feedback resistor R5 is disposed in a feedback path from an output end to the negative input end of the operational amplifier opa2. In this example, the resistance value of the feedback resistor R5 is variable. Feedback resistors R5 having different resistance values can be used depending on the specifications of the circuit.

The positive input end of the operational amplifier opa2 is connected to the reference power supply vref of the reference voltage vref and a ground gnd via a resistor network 14. One end of a set resistor R6 in the resistor network 14 is connected to the positive input end of the operational amplifier opa2. In this example, the resistance value of the set resistor R6 is variable. Set resistors R6 having resistance values corresponding to the resistance value of the feedback resistor R5 can be used depending on the specifications of the circuit.

A plurality of voltages obtained by dividing the reference voltage vref are supplied to the other end of the set resistor R6 in a switchable manner via a resistor group that can be switched for connection.

That is, the other end of the set resistor R6 is connected to an intermediate point of two division resistors R8a and R8b connected in series between the reference voltage vref and the ground gnd via an insertion resistor R7. In addition, one end of a parallel resistor R9, the other end of which is connected to the ground gnd, is connected to a contact point s1 of a switch SW, and the connection point between the set resistor R6 and the insertion resistor R7 is connected to a contact point s0 of the switch SW. The switch SW can switch the connection point of the division resistors R8a and R8b to the contact point s1 or the contact point s0 for connection.

When the contact point s0 is selected by the switch SW, the other end of the set resistor R6 is directly connected to the connection point of the division resistors R8a and R8b, and a voltage obtained by dividing the reference voltage vref by the division resistors R8a and R8b is supplied to the other end of the set resistor R6.

When the contact point s1 is selected by the switch SW, the other end of the set resistor R6 is connected to the connection point of the division resistors R8a and R8b via the insertion resistor R7, and the parallel resistor R9 is connected in parallel to the division resistor R8b. That is, the other end of the set resistor R6 is connected to the reference power supply vref via the insertion resistor R7 and the division resistor R8a, and is connected to the ground gnd by the insertion resistor R7 and the parallel connection of the division resistor R8b and the parallel resistor R9.

### “Operation of Preamplifier”

### <Adjustment of Input Voltage Va>

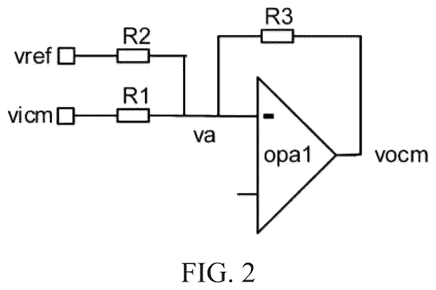

FIG. 2 is a diagram showing a common mode operation of the operational amplifier opa1 in the preamplifier 10.

In this example, an input vicm (vicm=(vip+vin)/2) is input to the negative input end of the operational amplifier opa1, and an output vocm (vocm=(vb+vc)/2) is obtained as a single output. It is assumed that the resistances of the respective paths are R1=R1a=R1b, R2=R2a=R2b, and R3=R3a=R3b. Thereby, it is possible to simulate the operation of the operational amplifier opa1 when there is no voltage between the positive and negative input ends.

When there is no input adjustment resistor R2, the input voltage va of the operational amplifier opa1 should be a voltage between vicm and vocm. When it is set that R3=2*R1 for the resistance and it is set that vicm=−2 V and vocm=2 V for the voltage, it becomes the input voltage va=−0.67 V<0 V as shown below.

$$va = vicm * R 3 / ( R 1 + R 3 ) + vocm * R 1 / ( R 1 + R 3 ) = ( - 2 V ) * 2 / 3 + 2 * 1 / 3 = - 0 \text{.67} V < 0 V$$

In addition, when it is set that R2=2*R1 for the input adjustment resistor R2 and it is set that vref=3 V for the reference voltage, it becomes the input voltage va=0.25 V>0 V as shown below.

$$va = ( - 2 / 3 ) V * 2 / ( 2 / 3 + 2 ) + 3 V * 2 / 3 / ( 2 / 3 + 2 ) = 0.25 V > 0 V$$

In this way, by adjusting the resistance value of the input adjustment resistor R2, the input voltage va of the operational amplifier opa1 can be adjusted to a desired range.

Therefore, in the configuration of FIG. 1, even if the lower voltage vin of the current detection resistor R0 is a negative voltage, the input voltage va of the operational amplifier opa1 can be set to a positive voltage by adjusting the resistance values of the input adjustment resistors R2a and R2b.

### <Common Mode and Feedback>

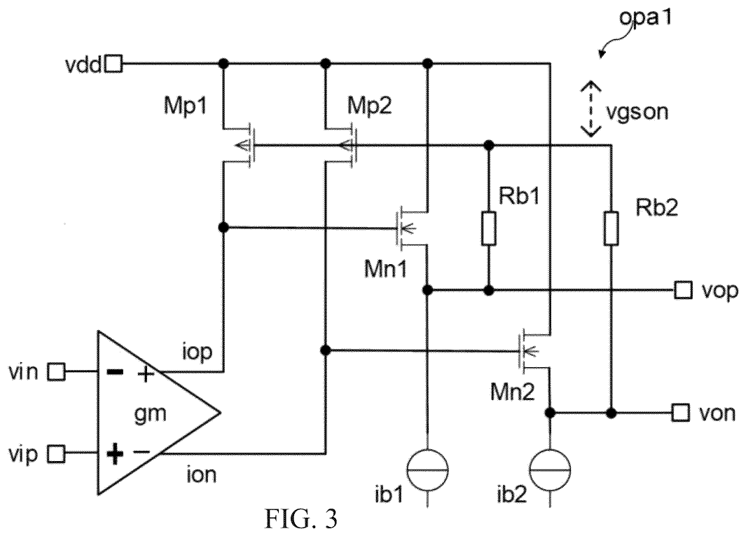

FIG. 3 is a diagram showing a detailed configuration of the operational amplifier opa1. In this manner, the upper voltage vip and the lower voltage vin are input to a positive input end and a negative input end of an input gain section gm, respectively. The input gain section gm outputs a positive current output iop and a negative current output ion in accordance with a difference between the two input ends.

The positive current output iop is connected to the drain of a p-channel transistor Mp1. The source of the p-channel transistor Mp1 is connected to a positive power supply vdd of a power supply voltage vdd. The negative current output ion is connected to the drain of a p-channel transistor Mp2. The source of the p-channel transistor Mp2 is connected to the positive power supply vdd.

The gate of an n-channel transistor Mn1 is connected to the drain of the p-channel transistor Mp1. The drain of the n-channel transistor Mn1 is connected to the power supply vdd, and the source is connected to a current source ib1 through which a current ib1 is made to flow, and is connected to a positive output vop that outputs the preamplifier negative output vb.

The gate of an n-channel transistor Mn2 is connected to the drain of the p-channel transistor Mp2. The drain of the n-channel transistor Mn2 is connected to the power supply vdd, and the source is connected to a current source ib2 through which a current ib2 is made to flow, and is connected to a negative output von that outputs the preamplifier positive output vc.

The gates of the p-channel transistors Mp1 and Mp2 are connected in common, the positive output vop is connected thereto via a pull-up resistor Rb1, and the negative output von is connected thereto via a pull-up resistor Rb2.

Accordingly, a voltage corresponding to the positive current output iop of the input gain section gm is output from the source of the n-channel transistor Mn1 to the positive output vop. In addition, a voltage corresponding to the negative current output ion of the input gain section gm is output from the source of the n-channel transistor Mn2 to the negative output von.

Here, the gate voltage of the p-channel transistors Mp1 and Mp2 when active is a value obtained by subtracting a gate-source voltage vgson of the p-channel transistors Mp1 and Mp2 when active from the source voltage, that is, vdd-vgson. Because the gates of the p-channel transistors Mp1 and Mp2 are connected to the positive output vop and the negative output von by the pull-up resistors Rb1 and Rb2, the output common voltage becomes (vop+von)/2=vdd−vgson.

In this way, the output common voltage is close to the power supply voltage vdd and is determined corresponding to the power supply voltage vdd. Therefore, the adjustment range can be made relatively large, the correction of the input common voltage performed on the operational amplifier opa1 according to the input adjustment resistors R2a and R2b becomes easy, and the input common voltage of the operational amplifier opa1 can be set relatively high.

In particular, in this example, native-type or depletion-type transistors are used as the n-channel transistors Mn1 and Mn2. Because the native-type or depletion-type transistors have a small gate-source voltage vgson when active, they can set the drain-source voltage of the p-channel transistors Mp1 and Mp2 to a value necessary and sufficient for the operation.

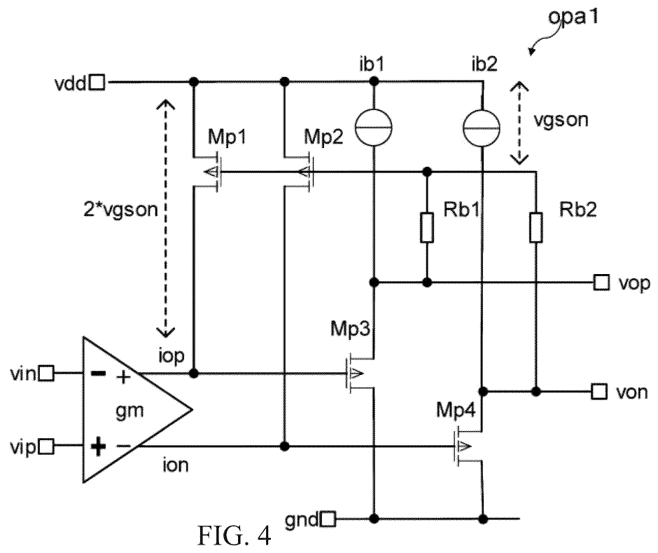

FIG. 4 is a diagram showing a configuration in a case where p-channel transistors Mp3 and Mp4 are used instead of the n-channel transistors Mn1 and Mn2 in the configuration of FIG. 3.

In this configuration, the current source ib1 is disposed between the source of the p-channel transistor Mp3 and the power supply vdd, and the drain of the p-channel transistor Mp3 is connected to the ground gnd. In addition, the current source ib2 is disposed between the source of the p-channel transistor Mp4 and the power supply vdd, and the drain of the p-channel transistor Mp4 is connected to the ground gnd. Further, the source of the p-channel transistor Mp3 is connected to the positive output vop, and the source of the p-channel transistor Mp4 is connected to the negative output von. In this case, in accordance with an output of the input gain section gm, the p-channel transistors Mp3 and Mp4 operate to obtain the positive output vop and the negative output von. Further, the common output voltage of the positive output vop and the negative output von becomes (vop+von)/2=vdd−vgson. For this reason, a relatively high input common voltage can be set in the operational amplifier opa1. The potential of the output of the input gain section gm becomes the power supply voltage vdd-2vgson, and the drain-source voltage of the p-channel transistors Mp1 and Mp2 can be set to a value necessary and sufficient for the operation.

### “Operation of Post-Amplifier”

Referring back to FIG. 1, the operation of the post-amplifier 12 will be described. The post-amplifier 12 is a single-ended amplifier that obtains a single output voltage vout in accordance with a difference between the input voltages vb and vc. Further, an amplification factor and an offset voltage are set according to the resistance values of the plurality of resistors around the operational amplifier opa2.

First, it is assumed that R8=R8a=R8b and R4=R4a=R4b for the resistance as set in a case of obtaining a general operation.

The gain of the post-amplifier 12 is R5/R4, and in this case, a combined resistance value between the positive input end of the operational amplifier opa2 and the power supply and the ground at the other end of the resistor network should be equal to R5. Moreover, the combined resistance value at this time is calculated on the assumption that there is a short between the reference power supply vref and the ground gnd. The reason is that it is assumed that the reference power supply vref is connected to an ideal power supply with a resistor of 0 ohm, and the ideal power supply is set to 0 V for calculation when the resistance value is considered.

Therefore, when s0 is selected in the switch SW, it becomes

$$R 5 = R 6 + R 8 / 2.$$

In this case, an offset voltage vd of the output of the operational amplifier opa2 relative to the ground gnd becomes

$$vd = vref * R 8 / ( R 8 + R 8 ) = v ref / 2.$$

On the other hand, when s1 is selected in the switch SW, it becomes

$$R 5 = R 6 + R 7 + ( R 8 / 2 ) // R 9.$$

Note that, the mark “//” represents a parallel connection.

Here, a condition when s0 is selected in the switch SW must be maintained, and it is denoted as

$$R 8 / 2 = R 7 + ( R 8 / 2 ) // R 9.$$

The resistance value of the parallel connection (//) of R8/2 and R9 is

$$( R 8 / 2 ) // R 9 = ( R 8 / 2 * R 9 ) / [ ( R 8 / 2 ) + R 9 ] ,$$

and therefore, it becomes

$$R 7 = R 8 * R 8 / [ 2 * ( R 8 + 2 * R 9 ) ] .$$

In a case where s1 is selected in the switch SW, when it is desired to set that the offset voltage vd=vref/8,

$$( R 9 // R 8 ) / ( R 9 // R 8 + R 8 ) = 1 / 8 ,$$

and it is sufficient that the resistance values of the resistors R9 and R7 are set as follows:

$$R 9 = R 8 / 6$$

$$R 7 = R 8 * R 8 / [ 2 * ( R 8 + 2 * R 9 ) ] = ( 3 / 8 ) * R 8 .$$

In this way, according to the embodiment, the offset voltage of the post-amplifier 12 can be set to two appropriate values (vref/2 and vref/8) by switching the switch SW.

In particular, the offset voltage can be set by setting the resistance values of the resistors R7, R8a, R8b, and R9, and can be set independently of the resistors R5 and R6, that is, separately from gain setting. In addition, the gain of the operational amplifier op2 can be set by changing the resistance values of the resistors R5 and R6. In FIG. 1, the resistors R5 and R6 are represented by variable resistors, indicating that the gain can be changed.

When the gain of the post-amplifier 12 is changed to 5 to 40, R5=5*R4 to 40*R4, and R6+R8/2=5*R4 to 40*R4. When R6=0, R8/2=5*R4, and R8=10*R4. That is, the resistance value of the resistor R8 can be increased to 10*R4, and the range of selection in the setting of the offset voltage is wide.

### Effects of Embodiments

The resistor network with a voltage setting switch of the post-amplifier can remove a buffer amplifier that may cause offsets and noise.

In the preamplifier 10, the input voltage of the operational amplifier opa1 can be adjusted by the setting of the resistance value of the input adjustment resistor R2 (R2a and R2b). Even if the input to the current sense amplifier 100 is a negative voltage, the operational amplifier opa1 can make the input voltage higher than the ground gnd by the setting of the input adjustment resistor R2.

By connecting the output section of the preamplifier 10 to the gate of the p-channel transistor whose source is connected to the power supply, an output voltage close to the power supply can be set, and the setting for the common mode input voltage of the preamplifier 10 becomes easy.

According to the post-amplifier related to the disclosure, by the resistor network, the offset voltage of the output can be set, and there is no need to use a component that causes noise mixing, such as a buffer amplifier.

Because it is able to change the resistance value of the resistor network connected to the positive input end of the post-amplifier by the switch, the offset voltage of the post-amplifier can be adjusted without changing the gain.

### DESCRIPTION OF THE REFERENCE NUMERALS

10: preamplifier
12: post-amplifier
14: resistor network
100: current sense amplifier

What is claimed is:

1. A current sense amplifier, comprising:
a preamplifier that has a preamplifier positive input end to which an upper voltage of a current detection resistor is input and a preamplifier negative input end to which a lower voltage of the current detection resistor is input, and obtains a preamplifier positive output at a positive output end and obtains a preamplifier negative output at a negative output end in accordance with a difference between the upper voltage and the lower voltage; and
a post-amplifier that has a post-amplifier negative input end to which the preamplifier negative output is input and a post-amplifier positive input end to which the preamplifier positive output is input, and obtains a post-amplifier output corresponding to a difference between the preamplifier positive output and the preamplifier negative output; wherein
the post-amplifier comprises:
a second operational amplifier in which the preamplifier negative output is input to a second operational amplifier negative input end, the preamplifier positive output is input to a second operational amplifier positive input end, and a second operational amplifier output is obtained based on a difference between them;
a second operational amplifier positive side input resistor disposed in an input path to the second operational amplifier positive input end;
a second operational amplifier negative side input resistor disposed in an input path to the second operational amplifier negative input end;
a second operational amplifier feedback resistor disposed in a feedback path from a second operational amplifier output end to the second operational amplifier negative input end; and
a resistor network which connects the second operational amplifier positive input end to a reference power supply and a ground, and in which a combined resistance value from the second operational amplifier positive input end to the reference power supply and the ground corresponds to the resistance value of the second operational amplifier feedback resistor.

2. The current sense amplifier according to claim 1, wherein
the resistor network comprises a set resistor of which one end is connected to the second operational amplifier positive input end, and a division resistor that obtains a voltage divided at an intermediate point of a plurality of series-connected resistors disposed between the reference power supply and the ground, and the other end of the set resistor is connected to the intermediate point.

3. The current sense amplifier according to claim 2, comprising:
an insertion resistor inserted between the other end of the set resistor and the intermediate point;
a parallel resistor of which one end is connected to the ground; and
a switch that selectively connects either the connection point between the set resistor and the insertion resistor or the other end of the parallel resistor to the intermediate point; wherein
by the switch, the voltage supplied to the other end of the set resistor is able to be changed while the resistance value from the other end of the set resistor to the reference power supply and the ground is maintained.

4. The current sense amplifier according to claim 3, wherein
the resistance values of the second operational amplifier feedback resistor and the set resistor are able to be changed, and
when the resistance value of the second operational amplifier feedback resistor is changed, a combined resistance value of the resistor network is maintained to be the same as the resistance value of the second operational amplifier feedback resistor by changing the resistance value of the set resistor.

5. A current sense amplifier, in which a pair of input signals corresponding to a voltage drop of a current detection resistor is input and an amplifier output is obtained,
the current sense amplifier comprising:
a positive input end to which a positive side signal of the pair of input signals is input;
a negative input end to which a negative side signal of the pair of input signals is input;
an output end that outputs an amplifier output corresponding to a difference between the positive side signal and the negative side signal;
a positive side input resistor disposed in an input path to the positive input end;
a negative side input resistor disposed in an input path to the negative input end;
a feedback resistor disposed in a feedback path from the output end to the second operational amplifier negative input end; and
a resistor network which connects the positive input end to a reference power supply and a ground, and in which a combined resistance value from the positive input end to the reference power supply and the ground corresponds to the resistance value of a second operational amplifier feedback resistor.
